(19) United States
(12) Patent Application Publication
(10) Pub. No.: US 2010/0186801 A1
(43) Pub. Date: Jul. 29, 2010

(54) PHOTOVOLTAIC MODULES WITH IMPROVED QUANTUM EFFICIENCY

(75) Inventors: Arno Boehm, Mannheim (DE); Axel Grimm, Heidelberg (DE); Bryce S. Richards, Edinburgh (GB)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, LUDWIGSHAFEN (DE)

(21) Appl. No.: 12/531,081

(22) PCT Filed: Mar. 12, 2008
(86) PCT No.: PCT/EP08/52912

§ 371 Date: Jan. 27, 2010

(30) Foreign Application Priority Data
Mar. 13, 2007 (EP) 07103987.9

(51) Int. Cl. H01L 31/0203; H01L 31/18

(52) U.S. Cl. 136/254; 438/64; 257/E31.117

(57) ABSTRACT

A photovoltaic module (110) is disclosed, which is suited for conversion of incident electromagnetic radiation (112) into electric energy. The photovoltaic module (110) comprises in order: a transparent cover sheet (114); and—at least one photovoltaic cell (116), wherein the at least one photovoltaic cell (116) is adapted to convert electromagnetic radiation (112) passing through the transparent cover sheet (114) into electric energy and wherein the photovoltaic cell (116) is accommodated within at least one encapsulation element (118) providing protection from environmental influence. The encapsulation element (118) comprises at least one luminescence downshifting material, which is adapted for at least partially absorbing the incident radiation (112) and for re-emitting radiation (112) at a longer wavelength.

The invention relates to photovoltaic modules for conversion of electromagnetic radiation into electric energy. The invention further relates to an encapsulation sheet material adapted for use in a photovoltaic module, and to a method of manufacturing a photovoltaic module.

### PRIOR ART

Photovoltaic modules for conversion of electromagnetic radiation, mainly within the ultraviolet, visible and/or infrared spectral range, are known in many variations and setups and may comprise photovoltaic cells functioning on a large number of physical principles.

Typically, photovoltaic modules comprise one or more photovoltaic cells, e.g. arranged in banks, which employ the photovoltaic effect of inorganic and/or organic semiconductor materials, in order to generate electricity in response to illumination by electromagnetic radiation.

Still, many photovoltaic modules, especially those produced in a large-scale production environment, exhibit a poor spectral response to short-wavelength light, i.e. mainly to light in the blue and/or ultraviolet spectral range. Thus, an appreciable fraction of the incident photons are absorbed in high recombination regions of the photovoltaic module, where the carriers are lost. For short-wavelength light, this happens mainly at the front surface of the modules. One known approach to rectifying such problems is to alter some of the processing steps in the device fabrication sequence in order to improve the electronic properties of the front surface of the photovoltaic modules. However, there are often technical hurdles that are difficult to overcome and design tradeoffs requiring a balance between optical and electrical performance.

The short-wavelength spectral response (i.e. mainly the number of electron-hole-pairs that are generated per incident photon) of many photovoltaic modules can be improved by the application of a luminescent downshifting layer on the photovoltaic module. This luminescence downshifting layer (LDS) typically contains a mixture of fluorescent organic dyes that are able to absorb short-wavelength light, where the photovoltaic module exhibits low external quantum efficiency, and re-emits this light at longer wavelength, i.e. in a range where the photovoltaic module exhibits a higher external quantum efficiency. This effect is widely described in the literature. Theoretical simulations of this effect are shown in B. S. Richards and K. R. McIntosh: Overcoming the Poor Short Wavelength Spectral Response of CdS/CdTe Photovoltaic Modules via Luminescence Down-Shifting: Ray-Tracing Simulations; Progress in Photovoltaics, Vol. 15, issue 1, January 2007, pages 27-34.

Still, the implementation of luminescence downshifting materials into photovoltaic modules involves a number of challenges, both with regard to materials and with regard to device setup. Thus, fluorescent organic dyes which may be used for luminescence down-shifting typically exhibit a rather poor photostability, typically lasting only days under solar illumination before photobleaching occurs. Further, in most cases, the luminescence downshifting materials are applied to the front of the photovoltaic modules or solar cells, e.g. by using a luminescence down-shifting coating on top of the modules. Nevertheless, the functioning of most fluorescent organic dyes requires the presence of a host environment, e.g. a host of a polymer, such as polymethylmethacrylate (PMMA). Still, materials such as PMMA cannot be simply incorporated into the glass typically used in photovoltaic industry, which is mostly a low-iron soda lime glass. This is mainly due to the fact that in glass manufacturing rather high temperatures are used, which are detrimental for the organic materials, such as PMMA.

Further, photovoltaic modules are required to withstand long periods of operation (e.g. more than 20 years) in harsh environments. Thus, the modules must withstand extreme exposure to ultraviolet radiation, large fluctuations in temperature, dust, hail, and sometimes very high humidity. These harsh environmental conditions are the main reasons why many manufacturers of photovoltaic modules prefer the use of glass cover sheets, which are well suited for withstanding harsh environmental conditions. In order to account for thermal expansion mismatch between the various photovoltaic module components, and in order to seal the edge of the photovoltaic module from weathering (i.e. mainly for preventing corrosion due to water vapour ingression), the solar cells are adhered to the glass with an encapsulation layer. As an encapsulant material, very often ethylene vinyl acetate (EVA) is used, typically in conjunction with various stabilizers and absorbers (see, e.g., A. W. Czandema and F. J. Pern: Encapsulation of PV Modules Using Ethylene Vinyl Acetate Copolymer as a Pottant: A Critical Review; Solar Energy Materials and Solar Cells, 1996, 43: 101-183). Still, other encapsulants, such as polyvinylbutyral (PVB), silicone or thermoplastic polyurethane, may be used.

### OBJECT OF THE INVENTION

It is therefore an object of the present invention to provide a photovoltaic module with improved quantum efficiency, which can be used in conjunction with traditional manufacturing and encapsulation methods, avoiding the challenges and shortcomings of known photovoltaic modules including luminescence downshifting materials.

### DISCLOSURE OF THE INVENTION

Thus, a photovoltaic module for conversion of incident electromagnetic radiation into electric energy, an encapsulation sheet material adapted for use in said photovoltaic module, and a method of manufacturing said photovoltaic module are proposed, which are suited to overcome the challenges and shortcomings of previously known modules, materials and methods.

The invention is mainly based on the finding that previously known techniques of implementing luminescence downshifting materials within the glass or polymeric cover sheet of the photovoltaic module or implementing the luminescence downshifting materials into a polymeric layer on the front surface of the photovoltaic module are disadvantages in many ways, as described above. Thus, in the photovoltaic module as proposed by the current invention, the luminescence downshifting material is comprised in an encapsulation element. Therefore, the photovoltaic module comprises in order the following elements: a transparent cover sheet and at least one photovoltaic cell, wherein the at least one photovoltaic cell is adapted to convert electromagnetic radiation passing through the transparent cover sheet into electric energy. The photovoltaic cell is further accommodated within at least one encapsulation element providing protection from environmental moisture. Said encapsulation element comprises the at least one luminescent downshifting material adapted for at least partially absorbing the incident radiation and for re-emitting this radiation at a longer wavelength.

Thus, the traditional and well-known setup of photovoltaic modules, comprising a transparent cover sheet, may be maintained, providing for a mechanical stability and the ability to withstand even harsh environmental conditions. The advantages of this “traditional” setup are combined with known advantages of luminescence downshifting, wherein the luminescence downshifting materials are well protected from photobleaching and weathering and may be embedded into a suitable host material. Thus, photovoltaic modules with suitable spectral response even in the short-wavelength spectral range may be achieved, without the necessity of implementing an extra step of manufacturing into the production of the photovoltaic modules.

Preferred embodiments of the invention are described in the dependent claims, the features of which may be implemented both separately and in combination. Thus, the transparent cover sheet may comprise a glass material, preferably a low-iron glass material, and/or a plastic material, such as a transparent polymer (e.g. polymethylmethacrylate, PMMA and/or ethylene tetrafluoroethylene, ETFE).

In a further preferred setup, the encapsulation element itself comprises a layer-by-layer-setup. Thus, the encapsulation element may comprise a front layer disposed between the photovoltaic cell and the transparent sheet. The luminescence downshifting material may be comprised within said front layer. Further, the encapsulation element may comprise a back layer disposed on a backside of the photovoltaic cell, opposing the front layer. Preferably, the encapsulation element comprises a laminated layer setup. Thus, the front layer may be at least partially laminated to the photovoltaic cell and/or to the back layer (or vice versa).

Additionally, the photovoltaic module may comprise an additional rear layer, wherein the rear layer is adapted for providing additional protection of the photovoltaic module against moisture. Thus, the rear layer may be laminated to the encapsulation element and/or to the transparent cover sheet. Preferably, as used in a preferred method of manufacturing of the photovoltaic element, a layer-by-layer-setup of the transparent cover sheet, the front layer, the photovoltaic cell, the back layer and (optionally) the rear layer is laminated in one or more lamination steps, in order to form the laminate photovoltaic module, which is protected against moisture and other detrimental environmental influences. The rear layer preferably comprises a fluorinated polymeric material. Thus, polyvinyl fluoride (trade name “Tedlar”) has proven to be a suitable material to be used in or as the rear layer.

The photovoltaic cell may comprise one or more inorganic and/or organic semiconductor materials which are known to the person skilled in the art and which are known from prior art photovoltaic modules. Thus, preferably, the photovoltaic cell may comprise at least one of the following materials: CdS; CdTe; Si, preferably p-doped Si or crystalline Si or amorphous Si or multicrystalline Si or polycrystalline Si; InP; GaAs; Cu₂S; CdS; Copper Indium Gallium Diselenide (CIGS).

The luminescence downshifting material may comprise one or more organic and/or inorganic luminescent materials. Thus, a single luminescence downshifting material may be used, or, alternatively or additionally, a “chain” of luminescence downshifting materials may be used, e.g. in order to provide a luminescence downshifting “cascade”. Preferably, one or more of the following materials are used (solely or as mixtures): an organic luminescent material, preferably Rhodamine, Coumarin, Rubrene, a laser dye, Alq₃, TPD, Gaq₂Cl; a perylene carbonic acid or a derivative thereof; a naphthalene carbonic acid or a derivative thereof; a violanthrone or an iso-violanthrone or a derivative thereof; an inorganic luminescent material, preferably Sm³⁺, Cr³⁺, ZnSe, Eu²⁺, Tb³⁺, a semiconducting quantum dot material, Ag nanoparticles. Therein, Alq₃ is aluminium tris-(8-hydroxyquinoline), TPD is N,N′-diphenyl-N,N′-bis-(3-methylphenyl)-1,1′-biphenyl-4-4′-diamine, and Gaq₂Cl denotes bis-(8-hydroxyquinoline)-chlorogallium.

Further, the concentration and the surrounding of the luminescence downshifting material may be improved. Thus, a concentration of the luminescence downshifting material of 20 ppm to 2000 ppm (corresponding to an optical density of 0.5 to 8), more preferably of 200 ppm to 1000 ppm (corresponding to an optical density of 1 to 4) has proven to exhibit advantageous effects with regard to improvement of the quantum efficiency for most of the luminescence downshifting material. Nevertheless, the precise optimum concentration may depend on the nature of the luminescence downshifting material (S) and/or the host material.

Further, in order to improve the spectral response in the short-wavelength region of many typical photovoltaic cells, it has proven to be advantageous if the luminescence downshifting material exhibits a maximum in absorption of electromagnetic radiation within a spectral range from 300 to 500 nanometers, preferably at approximately 400 nanometers. In this region, the spectral response of typical semiconductor materials used in prior art photovoltaic cells is significantly reduced. Further, preferably, the luminescence downshifting material may exhibit a maximum in emission of electromagnetic radiation within a spectral range from 400 to 700 nanometers, preferably within a range of 400 to 500 nanometers or within a range of 500 to 600 nanometers, and most preferably at approximately 500 nanometers. Within this spectral range, the spectral response of prior art photovoltaic cells is typically high, which means that the luminescence downshifting efficiently converts electromagnetic radiation from a range, in which the spectral response is poor, into a range in which the spectral response of the photovoltaic cell is higher.

Further, as outlined above, the encapsulation element may comprise at least one polymeric matrix material suited for a thermal lamination process. Thus, the lamination setup of the photovoltaic module as outlined above can be implemented. As a preferred material, ethylene vinyl acetate (EVA) and/or polyvinylbutyral (PVB) and/or ethylene tetrafluoroethylene (ETFE) have shown to exhibit both suitable lamination properties and have proven to provide a suitable matrix for the luminescence downshifting material. Nevertheless, other laminate or matrix materials may be used as well, such as polyvinylbutyral (PVB), polyurethane, silicone or mixtures thereof. The at least one luminescence downshifting material may at least partially be dissolved or dispersed in the polymeric matrix material.

In the previously mentioned embodiments, the luminescence downshifting material was embedded and/or dissolved directly (i.e. single phase) within the laminate matrix material. Nevertheless, in this case, the matrix material both has to fulfil the technical requirements for lamination and for embedding (i.e. being a suitable matrix material for) the luminescence downshifting material. Therefore, additionally or alternatively, the photovoltaic module may further comprise at least one additional host material, wherein the luminescence downshifting material is at least partially dissolved or dispersed in the host material and wherein the host material is dispersed in the polymeric matrix material. Thus, a setup comprising two or more phases may be created.

As host materials to be dispersed in the polymeric matrix material (two or more phase setup) or for use as a matrix material in the single-phase setup mentioned above, the following materials have proven to be suitable: PMMA, PVB, polyurethane, silicone, crystalline KMgF₃, Al₂O₃, ZnSe, CaF₂, glass, ORMOSIL, PLMA, PEMA, PBMA, PVT, PC, PS, Alq₃, TPD, Gaq₂Cl or mixtures of the aforementioned materials. Thereof, PMMA denotes polymethylmethacrylate, PVB denotes polyvinylbutyral, PLMA denotes polylaurylmethacrylate, PEMA denotes polyethylmethacrylate, PBMA denotes polyisobutylmethacrylate, PVT denotes polyvinyltoluene, PC denotes polycarbonate, and PS denotes polystyrene. For the further materials and abbreviations, see the explanations outlined above.

As outlined above, the downshifting materials may preferably comprise a dye comprising one or more of the group consisting of a perylene carbonic acid or a derivative thereof, a naphthalene carbonic acid or a derivative thereof, a violanthrone or an isoviolanthrone or a derivative thereof.

As a fluorescent dye based on a perylene carbonic acid or a derivative thereof (in the following: “perylene dye”), preferably one or more of the following dyes may be used: a perylene tetracarbonic acid diimide, a perylene tetracarbonic acid monoanhydride monoimide, a perylene tetracarbonic acid dianhydride, a perylene dicarbonic acid imide, a perylene-3,4-dicarbonic acid anhydride, a perylene dicarbonic acid ester, a perylene dicarbonic acid amide. Thereof, the most preferred are perylene dicarbonic acids, perylene dicarbonic acid imides or perylene tetracarbonic acid diimides or combinations thereof.

Therein, perylene dicarbonic acid imides are derived from perylene-3,4-dicarbonic acid, and perylene dicarbonic acid esters and amides are derived from isomeric perylene-3,9- and -3,10-dicarbonic acids.

Of the perylene carbonic acid imides, hydrogen or C₁-C₁₈-alkyl are especially suited as substituents on the imide nitrogen atom.

The perylene dyes may be unsubstituted. However, preferably, they are substituted by 1 to 5 (in case of perylene tetracarbondiimide preferably 2 to 4) (het)aryloxy- or (het)arylthio substituent R.

The substituent R is defined as follows:

R aryloxy, arylthio, hetaryloxy or hetarylthio, annulated with saturated or unsaturated 5- to 7-membered ring systems, which carbon atom backbone can be interrupted with one or more functional groups of —O—, —S—, —NR¹—, —N═CR¹—, —CO—, —SO— and/or —SO₂—, whereas the whole ring system can be substituted by one or more substituent (i), (ii), (iii), (iv) and/or (v):
(i) C₁-C₃₀-alkyl, which carbon atom chain can be interrupted by one or more groups of —O—, —S—, —NR¹—, —N═CR¹—, —C═C—, —CR¹═CR¹—, —CO—, —SO— and/or —SO₂— and can be substituted by one or more substituent of: C₁-C₁₂-alkoxy, C₁-C₆-alkylthio, —C≡CR¹, —CR¹═CR¹₂, hydroxy, mercapto, halogen, cyano, nitro, —NR²R³, —NR²COR³, —CONR²R³, —SO₂NR²R³, —COOR², —SO₃R², aryl and/or saturated or unsaturated C₄-C₇-cycloalkyl, which carbon atom backbone can be interrupted by one or more groups of —O—, —S—, —NR¹—, —N═CR¹—, —CR¹═CR¹—, —CO—, —SO— and/or —SO₂—, whereas each of the aryl- and cycloalkyl substituent can be substituted by one or more substituent of C₁-C₁₈-alkyl and/or the previously as substituents for alkyl mentioned substituents.
(ii) C₃-C₈-cycloalkyl, which carbon atom backbone can be interrupted by one or more groups of —O—, —S—, —NR¹—, —N═CR¹—, —CR¹═CR¹—, —CO—, —SO— and/or —SO₂— annulated with saturated or unsaturated 5- to 7-membered ring systems, which carbon atom backbone can be interrupted with one or more functional groups of —O—, —S—, —NR¹—, —N═CR¹—, —CR¹═CR¹—, —CO—, —SO— and/or —SO₂—, whereas the whole ring system can be substituted by one or more substituents of:
C₁-C₁₈-alkyl, C₁-C₁₂-alkoxy, C₁-C₆-alkylthio, —C≡CR¹, —CR¹═CR¹₂, hydroxy, mercapto, halogen, cyano, nitro, —NR²R³, —NR²COR³, —CONR²R³, —SO₂NR²R³, —COOR² and/or —SO₃R²;
(iii) aryl or hetaryl, which can be annulated with further saturated or unsaturated 5- to 7-membered rings, which carbon atom backbone can be interrupted by one or more groups of —O—, —S—, —NR¹—, —N═CR¹—, —CR¹═CR¹—, —CO—, —SO— and/or —SO₂—, whereas the whole ring system can be substituted by one or more substituents of: C₁-C₁₈-alkyl, C₁-C₁₂-alkoxy, C₁-C₈-alkylthio, —C≡CR¹, —CR¹═CR¹₂, hydroxy, mercapto, halogen, cyano, nitro, —NR²R³, —NR²COR³, —CONR²R³, —SO₂NR²R³, —COOR², —SO₃R², aryl and/or hetaryl, which by itself can be substituted by C₁-C₁₈-alkyl, C₁-C₁₂-alkoxy, hydroxy, mercapto, halogen, cyano, nitro, —NR²R³, —NR²COR³, —CONR²R³, —SO₂NR²R³, —COOR² and/or —SO₃R²
(iv) one substituent —U-aryl, which can be substituted by one or more of the above mentioned substituents of the aryl substituent (iii), whereas U can be a group of —O—, —S—, —NR¹—, —CO—, —SO— or —SO₂—;
(v) C₁-C₁₂-alkoxy, C₁-C₆-alkylthio, —C≡CR¹, —CR¹═CR¹₂, hydroxy, mercapto, halogen, cyano, nitro, —NR²R³, —NR²COR³, —CONR²R³, —SO₂NR²R³, —COOR² or —SO₃R², whereas the substituent R for n>1 can be identical or different from each other;
R¹ hydrogen or C₁-C₁₈-alkyl, whereas the residual R¹ can be identical or different, if they appear multiple times;
R², R³ independently hydrogen;
C₁-C₁₈-alkyl, which carbon atom chain can be interrupted with one or more groups of —O—, —S—, —CO—, —SO— and/or —SO₂— and can be substituted one or more times by C₁-C₁₂-alkoxy, C₁-C₆-alkylthio, hydroxy, mercapto, halogen, cyano, nitro and/or —COOR¹; aryl or hetaryl, which can be annulated by additional saturated or unsaturated 5- to 7-membered rings, which carbon atom backbone can be interrupted by one or more groups of —O—, —S—, —CO— and/or —SO₂—, whereas the complete ring system can be substituted one or more times by C₁-C₁₂-alkyl and/or the previously mentioned substituents of alkyl.

In addition, perylene dyes can be substituted by cyanogroups. This substitution has great importance for perylene dicarbonic acid imide and perylene dicarbonic acidesters.

The following examples of especially suited perylene dyes shall be mentioned: N,N′-Bis(2,6-diisopropylphenyl)perylene-3,4:9,10-tetracarbonic acid diimide, N,N′-Bis(2,6-dimethylphenyl)perylene-3,4:9,10-tetracarbonic acid diimide, N,N′-Bis(7-tridecyl)perylene-3,4:9,10-tetracarbonic acid diimide, N,N′-Bis(2,6-diisopropylphenyl)-1,6,7,12-tetra(4-tert-octylphenoxy)perylene-3,4:9,10-tetracarbonic acid diimide, N,N′-Bis(2,6-diisopropylphenyl)-1,6,7,12-tetraphenoxyperylene-3, 4:9, 10-tetracarbonic acid diimide, N,N′-Bis(2,6-diisopropylphenyl)-1,6- and -1,7-bis(4-tert.-octylphenoxy)perylene-3,4:9,10-tetracarbonic acid diimide, N,N′-Bis(2,6-diisopropylphenyl)-1,6- and -1,7-bis(2,6-diisopropylphenoxy)-perylene-3,4:9,10-tetracarbonic acid diimide, N-(2,6-diisopropylphenyl)perylene-3,4-dicarbonic acid imide, N-(2,6-diisopropylphenyl)-9-phenoxyperylene-3,4-dicarbon acid imide, N-(2,6-diisopropylphenyl)-9-(2,6-diisopropylphenoxy)perylene-3,4-dicarbonic acid imide, N-(2,6-diisopropylphenyl)-9-cyanoperylene-3,4-dicarbonic acid imide, N-(7-tridecyl)-9-phen-oxyperylene-3,4-dicarbonic acid imide, perylene-3,9- and -3,10-dicarbonic acid diisobutyl-ester, 4,10-dicyanoperylene-3,9- and 4,9-dicyanoperylene-3,10-dicarbonic acid diisobutyl-ester and perylene-3,9- and -3,10-dicarbonic acid di(2,6-diisopropylphenyl)amide.

Perylene dyes are well known respectively described in older German patent literature 10 2005 032 583.1 (substitution with ortho,ortho′-disubstituted (thio)phenoxy substituent R). They usually absorb in the wavelength region of 360 to 630 nm and emit between 470 to 750 nm.

Besides perylene dyes, other fluorescent dyes having similar structures may be employed, such as dyes on the basis of violanthrones and/or iso-violanthrones, such as the structures disclosed in EP-A-073 007. As a preferred example of well suited materials, alkoxylated violanthrones and/or iso-violanthrones, may be employed, such as 6,15-didodecyloxyisoviolanthronedion-(9,18).

Finally, as a further example of suitable fluorescent dyes, dyes on the basis of naphthalencarbonic acid derivatives may be named. Fluorescent dyes on the basis of naphthalene typically exhibit an absorption within the UV range at wavelengths of approx. 300 to 420 nm and exhibit an emission range at approx. 380 to 520 nm. Thus, as a further advantage, these dyes not only effect an efficient conversion of UV light into longer wavelength light, but also may form an efficient protection of the conversion solar cells against UV radiation.

Within the naphthalene carbonic acid derivatives, the most preferred are imides (e.g. naphthalene-1,8:4,5-tetracarbonic acid diimides, and especially naphthalene-1,8-dicarbonic acid imides, most preferably 4,5-dialkoxynaphthalene-1,8-dicarbonic acid monoimides and 4-phenoxynaphthalene-1,8-dicarbonic acid monoimides, which are, in the following, abbreviated by “naphthalic imides”). Naphthalic imides, especially naphthalene-1,8:4,5-tetracarbonic acid diimides, may also be unsubstituted in the naphthalene frame. Nevertheless, preferrably, especially the naphthalene dicarbonic acid imides have one or preferably two alkoxy-, aryloxy- or cyano groups as substituents.

The alkoxy groups preferably comprise 1 to 24 C-atoms. Within the aryloxy groups, most preferred are phenoxy moieties, which may be unsubstituted or substituted.

As examples of naphthalic imides which are especially well suited, the following may be named: N-(2-ethylhexyl)-4,5-dimethoxynaphthalene-1,8-dicarbonic acid imide, N-(2,6-diisopropyl-phenyl)-4,5-dimethoxynaphthalene-1,8-dicarbonic acid imide, N-(7-tridecyl)-4,5-dimethoxy-naphthalene-1,8-dicarbonic acid imide, N-(2,6-diisopropylphenyl)-4,5-diphenoxynaphthalene-1,8-dicarbonic acid imide and N,N′-Bis(2,6-diisopropylphenyl)-1,8:4,5-naphthalene tetracarbonic acid diimide.

### DESCRIPTION OF PREFERRED EMBODIMENTS

For a more complete understanding of the present invention, reference is established to the following description of preferred embodiments made in connection with the accompanying drawings, in which:

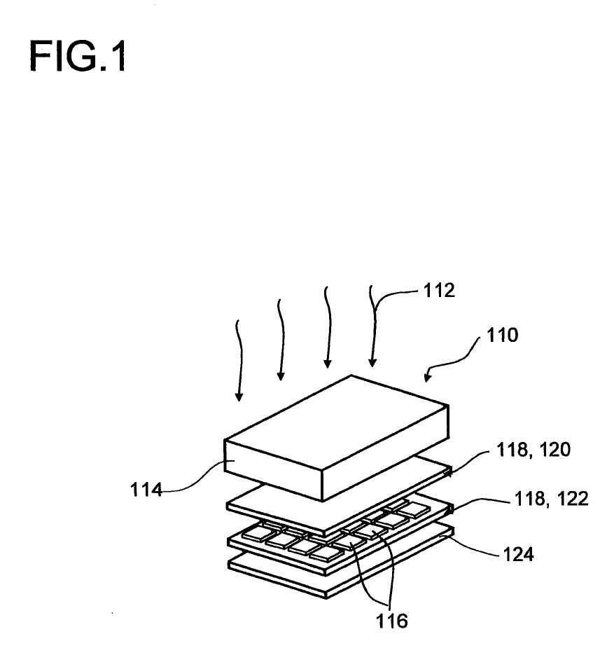

FIG. 1 shows a perspective view of a preferred embodiment of a photovoltaic module.

In FIG. 1, a perspective view of a preferred embodiment of a photovoltaic module 110 according to the invention is depicted. The embodiment is intended for illustrative purposes only, and the invention is not limited to the embodiment as depicted.

The photovoltaic module 110 is adapted for converting electromagnetic radiation (in FIG. 1 symbolically denoted by referential 112), preferably visible, infrared and/or ultraviolet light, into electric energy. For this purpose, the photovoltaic module 110 comprises a transparent cover sheet 114, which may be composed of one or more of the materials listed above, and which preferably comprises glass, preferably low-iron soda lime glass, and/or a transparent plastic material, such as PMMA and/or polycarbonate. Preferably, the cover sheet 114 exhibits a transmission above 50%, preferably above 90% over the full range of the visible spectrum. Further, the cover sheet 114 may be rigid, or it may provide flexible properties, such as properties allowing for at least moderate bending of the cover sheet, in order to allow for use of the photovoltaic module 110 in applications in which such flexible properties are required, such as, e.g., for use in credit cards or the like.

Beneath the cover sheet 114, photovoltaic cells 116 are arranged. In the embodiment shown in FIG. 1, these photovoltaic cells 116 are arranged in a rectangular pattern. Nevertheless, other arrangements can be used.

The photovoltaic cells 116 may comprise any photovoltaic technique known to the person skilled in the art, such as the techniques listed in the description above. In the following, it is assumed that the photovoltaic cells 116 depicted in FIG. 1 comprise standard silicon materials. Further, appropriate wiring and, optionally, at least part of an electronic driving circuitry may be provided within the photovoltaic module 110, which is not depicted in FIG. 1.

In the embodiment of the photovoltaic module 110 as depicted in FIG. 1, the photovoltaic cells 116 are sandwiched between two layers of an encapsulation element 118: a front layer 120 and a back layer 122. Preferably, both layers 120, 122 comprise ethylene vinyl acetate (EVA), preferably of a thickness of 0.2-1.0 mm, most preferably of approximately 0.5 mm. The encapsulation element 118 provides structural support and positioning for the photovoltaic cells 116 and/or the circuit assembly during fabrication, handling, storage, transportation, installation and operation (especially in the weathering terrestrial environment). Further, the encapsulation element 118 may achieve and maintain maximum optical coupling between the photovoltaic cells 116 and the incident electromagnetic radiation 112, such as solar radiation, in a prescribed spectral region within initial transmission of preferably at least 90%, and a loss of preferably less than 5% over the twenty years. Further, the encapsulation element 118 may provide a physical isolation of the photovoltaic cells 116 and, optionally, further circuit components, from exposure to hazardous or degrading environmental factors (e.g. reactive elements/compounds, hail, salt spray, birds). The encapsulation element 118 preferably achieves and maintains reliable electrical isolation of the photovoltaic cells 116, and, optionally, further circuit elements of the photovoltaic cells 116, from both operational and safety viewpoints during the useful life of the photovoltaic module 110. Further, the encapsulation element 118 may comprise and provide ancillary electrical circuitry (e.g. interconnects) for the photovoltaic cells 116 within a photovoltaic module 110.

The layers 120, 122 of the encapsulation element 118, preferably EVA, may be supplied to manufacturers of the photovoltaic module 110 on roles and may then be cut to size.

As proposed by the invention, the encapsulation element 118, preferably the front layer 120, comprises the at least one luminescence downshifting material, which is adapted for at least partially absorbing the incident magnetic radiation 112 and re-emitting radiation at a longer wavelength. Thus, as outlined above, luminescent materials such as fluorescent organic dyes or semiconductor quantum dots (nanocrystals) can be incorporated into the encapsulation element 118, preferably into the front layer 120.

For this incorporation, the following ways may be used: First, organic dyes may be dissolved directly into the polymeric material of the encapsulation element 118. Thus, fluorescent dyes such as those in the BASF Lumogen F series (perylene dyes, see description listed above) can tolerate relatively high temperatures and will not be adversely affected during the lamination process at 150° C. (see below). Secondly, additionally or alternatively, particles of dye-doped PMMA or semiconductor quantum dots (nanocrystals) may be mixed in together with a polymeric material of the encapsulation element 118. Further ways of providing the encapsulation element 118 with the luminescence downshifting material are outlined above.

Further, the photovoltaic module 110 of the embodiment shown in FIG. 1 comprises a rear layer 124. For this rear layer 124, preferably, a fluorinated polymeric material is used, such as Tedlar. Tedlar is a material designed to prevent moisture ingression into the rear end of the photovoltaic module 110, and is both cheaper and lighter than the possibility of using a rear glass sheet.

The setup of the photovoltaic module 110 as depicted in FIG. 1 may be assembled using standard lamination techniques. Thus, the cover sheet 114, the front layer 120, the photovoltaic cells 116, the back layer 122 and the rear layer 124 may be placed into a vacuum laminator for 10 to 20 minutes at a temperature of e.g. up to 150° C., in order to achieve three-dimensional crosslinking of the polymeric material of the encapsulation element 118, preferably the EVA polymer. Further, the rear layer 124 is laminated to the other layers, preferably within the same manufacturing step.

The approach for the formation of the luminescence downshifting layer by incorporating the luminescence downshifting material into the encapsulation element 118, preferably into the front layer 120, provides a significant boost in the short-wavelength response of the photovoltaic module 110, and, hence, the amount of photogenerated current. The approach can be applied to approximately 95% of photovoltaic modules 110 produced today, including all silicon wafer based devices, as well as some thin-film photovoltaic modules 110 that are deposited onto a substrate. In the latter case, encapsulation to a front cover sheet is required. No additional processing steps are necessary, as compared to standard manufacturing techniques used today.

Multiple dyes (such as dye mixtures) may be selected in order to cover the region of poor quantum efficiency for the relevant photovoltaic modules 110 due to their relatively narrow absorption band (see e.g. the graph of the external quantum efficiency as a function of the wavelength shown in B. S. Richards and K. R. McIntosh: Overcoming the Poor Short Wavelength Spectral Response of CdS/CdTe Photovoltaic Modules via Luminescence Down-Shifting: Ray-Tracing Simulations; Progress in Photovoltaics, Vol. 15, issue 1, January 2007, pages 27-34). Dyes are typically selected starting from the ultraviolet range and then adding dyes that exhibit shorter wavelength absorption and emission spectra. For fluorescent dyes that exhibit a high luminescence quantum efficiency, a mixed broad-band absorber will still exhibit a high luminescence quantum efficiency, which exhibits the majority of its emission via the longest wavelength dye due to the energy cascading down to the lowest energy. Mixtures of dyes and coating layers may be found in the literature cited above.

### LIST OF REFERENCE NUMBERS

110 photovoltaic module
112 electromagnetic radiation
114 cover sheet
116 photovoltaic cells
118 encapsulation element
120 front layer
122 back layer
124 rear layer

1-24. (canceled)

25. A photovoltaic module for the conversion of incident electromagnetic radiation into electric energy, comprising in order:
a transparent cover sheet; and
at least one photovoltaic cell, wherein the at least one photovoltaic cell is adapted to convert electromagnetic radiation passing through the transparent cover sheet into electric energy and wherein the photovoltaic cell is accommodated within at least one encapsulation element providing protection from environmental influence,
wherein the encapsulation element comprises at least one luminescence down-shifting material adapted for at least partially absorbing the incident radiation and re-emitting radiation at a longer wavelength.

26. The photovoltaic module according to claim 25, wherein the transparent cover sheet comprises at least one of the following materials: a glass material; and a plastic material.

27. The photovoltaic module according to claim 25, wherein the encapsulation element comprises a front layer disposed between the photovoltaic cell and the transparent cover sheet.

28. The photovoltaic module according to claim 27, wherein said front layer comprises the luminescence down-shifting material.

29. The photovoltaic module according to claim 27, wherein the encapsulation element further comprises a back layer disposed on a back side of the photovoltaic cell opposing the front layer.

30. The photovoltaic module according to claim 27, wherein the front layer is at least partially laminated to the photovoltaic cell and/or to the back layer.

31. The photovoltaic module according to claim 25, further comprising an additional rear layer, wherein the rear layer is adapted for providing additional protection of the module against environmental influence.

32. The photovoltaic module according to claim 31, wherein the rear layer is laminated to the encapsulation element and/or to the transparent cover sheet.

33. The photovoltaic module according to claim 32, wherein the rear layer comprises a fluorinated polymeric material.

34. The photovoltaic module according to claim 25, wherein the luminescence downshifting material comprises at least one of the following materials: an organic luminescent material; a perylene dye; a naphthalene carbonic acid or a derivative thereof; a violanthrone or an iso-violanthrone or a derivative thereof; and an inorganic luminescent material.

35. The photovoltaic module according to claim 34, wherein the luminescence down-shifting material comprises a perylene dye, wherein the perylene dye comprises at least one of the following: N,N′-Bis(2,6-diisopropylphenyl)perylene-3,4:9,10-tetracarbonic acid diimide, N,N′-Bis(2,6-dimethylphenyl)perylene-3,4:9,10-tetracarbonic acid diimide, N,N′-Bis(7-tridecyl)perylene-3,4:9,10-tetracarbonic acid diimide, N,N′-Bis(2,6-diisopropylphenyl)-1,6,7,12-tetra(4-tert.-octylphenoxy)perylene-3,4:9,10-tetracarbonic acid diimide, diisopropylphenyl)-1,6,7,12-tetraphenoxyperylene-3,4:9,10-tetracarbonic acid diimide, N,N′-Bis(2,6-diisopropylphenyl)-1,6- and -1,7-bis(4-tert.-octylphenoxy)perylene-3,4:9,10-tetracarbonic acid diimide, N,N′-Bis(2,6-diisopropylphenyl)-1,6- and -1,7-bis(2,6-diisopropylphenoxy)-perylene-3,4:9,10-tetracarbonic acid diimide, N-(2,6-diisopropylphenyl)perylene-3,4-dicarbonic acid imide, N-(2,6-diisopropylphenyl)-9-phenoxyperylene-3,4-dicarbon acid imide, N-(2,6-diisopropylphenyl)-9-(2,6-diisopropylphenoxy)perylene-3,4-dicarbonic acid imide, N-(2,6-diisopropylphenyl)-9-cyanoperylene-3,4-dicarbonic acid imide, N-(7-tridecyl)-9-phenoxyperylene-3,4-dicarbonic acid imide, perylene-3,9- and -3,10-dicarbonic acid diisobutyl-ester, 4,10-dicyanoperylene-3,9- and 4,9-dicyanoperylene-3,10-dicarbonic acid diisobutyl-ester and perylene-3,9- and/or -3,10-dicarbonic acid di(2,6-diisopropylphenyl)amide.

36. The photovoltaic module according to claim 25, wherein the luminescence down-shifting material comprises at least one violanthrone and/or isoviolanthrone.

37. The photovoltaic module according to claim 25, wherein the luminescence down-shifting material comprises at least one naphthalic imide, wherein the naphthalic imide comprises at least one of the following materials: N-(2-ethylhexyl)-4,5-dimethoxynaphthalene-1,8-dicarbonic acid imide, N-(2,6-diisopropyl-phenyl)-4,5-dimethoxynaphthalene-1,8-dicarbonic acid imide, N-(7-tridecyl)-4,5-dimethoxy-naphthalene-1,8-dicarbonic acid imide, N-(2,6-diisopropylphenyl)-4,5-diphenoxynaphthalene-1,8-dicarbonic acid imide, and N,N′-Bis(2,6-diisopropylphenyl)-1,8:4,5-naphthalene tetracarbonic acid diimide.

38. The photovoltaic module according to claim 25, wherein the luminescence down-shifting material is comprised within the encapsulation element at a concentration of 20 ppm to 2000 ppm.

39. The photovoltaic module according to claim 25, wherein the luminescence down-shifting material exhibits a maximum in absorption of electromagnetic radiation within a spectral range from 300 to 500 nanometers.

40. The photovoltaic module according to claim 25, wherein the luminescence down-shifting material exhibits a maximum in emission of electromagnetic radiation within a spectral range from 400 to 700 nanometers.

41. The photovoltaic module according to claim 25, wherein the encapsulation element comprises at least one polymeric matrix material suited for a thermal lamination process and at least one luminescence downshifting material.

42. The photovoltaic module according to claim 41, wherein the luminescence down-shifting material is at least partially dissolved or dispersed in the polymeric matrix material.

43. The photovoltaic module according to claim 41, further comprising at least one additional host material, wherein the luminescence downshifting material is at least partially dissolved or dispersed in the host material and wherein the host material is dispersed in the polymeric matrix material.

44. The photovoltaic module according to claim 43, wherein the host material comprises at least one of the following materials: PMMA, PVB, crystalline KMgF₃, Al₂O₃, ZnSe, CaF₂, glass, ORMOSIL, PLMA, PEMA, PC, PBMA, PVT, and PS.

45. The photovoltaic module according to claim 25, wherein the photovoltaic cell comprises at least one of the following materials: CdS; Si; CdTe; InP; GaAs; Cu₂S; CdS; and Copper Indium Gallium Diselenide (CIGS).

46. An encapsulation sheet material adapted for use in an encapsulation element in a photovoltaic module according to claim 25, encapsulation sheet material comprising at least one luminescence downshifting material and at least one polymeric matrix material.

47. A method of manufacturing a photovoltaic module according claim 25, the method comprising providing in order the following elements: a transparent cover sheet, a front layer of the encapsulation element comprising the luminescence downshifting material, a photovoltaic cell and a back of the layer of the encapsulation element; and laminating said elements to form a laminate photovoltaic module.

48. The method according to claim 47, the method further comprising the step of providing a rear layer.
